(19) United States
(12) Patent Application Publication
(10) Pub. No.: US 2026/0321301 A1
(43) Pub. Date: Oct. 15, 2026

(54) MEMORY WITH REDUCED LEAKAGE THROUGH ANALOG HEAD SWITCH CONTROL

(71) Applicant: QUALCOMM Incorporated, San Diego, CA (US)

(72) Inventors: Meysam AZIN, San Diego, CA (US); Seohee KIM, San Diego, CA (US); Andrew WEIL, San Diego, CA (US); Parisa MAHMOUDIDARYAN, San Diego, CA (US); Dongwon SEO, San Diego, CA (US); Chulmin JUNG, San Diego, CA (US); Yi-Ju CHEN, Toufen City (TW); Jiajing CHEN, Taoyuan City (TW)

(21) Appl. No.: 19/175,923

(22) Filed: Apr. 10, 2025

(51) Int. Cl. G11C 5/14; G05F 1/575

(52) U.S. Cl. CPC G11C 5/147; G05F 1/575

(57) ABSTRACT

A memory is provided that includes an analog gate voltage driver that drives the gate of an NMOS head switch transistor for a bitcell array with an analog gate voltage while the bitcell array operates in a light-sleep mode. The analog gate voltage switches the NMOS head switch transistor partially on so that the head switch transistor passes a reduced power supply voltage despite being powered by a memory power supply voltage that is greater than the reduced power supply voltage. A PMOS head switch transistor that is coupled in parallel with the NMOS head switch transistor between a power supply node for the memory power supply and an input power node to the bitcell array is switched off during the light-sleep mode and switched on while the bitcell array operates in an active mode.

### TECHNICAL FIELD

The present application relates generally to memories and, more specifically, to memories having reduced leakage through analog head switch control.

### BACKGROUND

An integrated circuit with an embedded memory such as a static random-access memory (SRAM) will typically have various operating modes in which a memory power supply voltage for the embedded memory is varied according to the operating mode. With respect to these modes, the integrated circuit may be divided into separate power domains. A core domain (CX) power supply voltage (VDDCX) powers a core domain including a processor whereas a memory domain (MX) power supply voltage (VDDMX) powers the bitcells of the SRAM. But an SRAM does not consist merely of the bitcells but also includes a memory periphery that includes components such as address decoders and other logic. A majority of the memory periphery is contained within the MX domain and may thus be denoted as an MX periphery but there is also a CX domain portion of the memory periphery for components such as level-shifters. The CX domain portion of the memory periphery may also be denoted as the CX periphery. An SRAM may thus be divided into a CX domain portion including the CX periphery and an MX domain including the bitcell array and the MX periphery.

To reduce power consumption and increase battery life, the memory may be placed into a deep-sleep mode in which the bitcell domain, the periphery CX domain, and the periphery MX domain are all powered down. This involves the switching off the head switch transistors that couple between the power rails for the VDDCX and VDDMX power supply voltages and the corresponding power domains. In a default mode (which may also be denoted as an active mode of operation), the head switch transistors are all on so that the corresponding power domains are all fully powered. In addition, the memory power domain supply voltage VDDMX is sufficiently elevated during the active mode for increased memory speed. During a retention mode, the head switch transistors for the periphery MX and CX domains are powered off. The head switch transistors for the bitcell MX domain remain on so that the bitcells may retain their stored binary content during the retention mode but the memory power domain supply voltage is lowered from its active value to a retention value so that the bitcells have reduced leakage during the retention mode.

In accordance with an aspect of the disclosure, a memory is provided that includes: a power supply node for a memory power supply voltage; a first n-type metal-oxide semiconductor (NMOS) transistor; a first p-type metal-oxide semiconductor (PMOS) transistor; a bitcell array having an input power node for a bitcell power supply voltage, wherein the first NMOS transistor and the first PMOS transistor are coupled in parallel between the power supply node and the input power node; and a voltage regulator configured to control an analog gate voltage of the first NMOS transistor to regulate the bitcell power supply voltage.

In accordance with another aspect of the disclosure, a memory is provided that includes: a voltage rail for a memory power supply voltage; a plurality of banks, each bank including an array of bitcells; a plurality of head switch circuits corresponding to the plurality of banks on a one-to-one basis, wherein each bank’s array of bitcells is coupled to the voltage rail through a corresponding head switch circuit from the plurality of head switch circuits, and wherein each head switch circuit includes: a first NMOS transistor coupled between the voltage rail and an output node of the head switch circuit; and a voltage regulator configured to control an analog gate voltage of the first NMOS transistor during both a light-sleep mode and an active mode for the corresponding bank.

In accordance with yet another aspect of the disclosure, a method of powering a memory is provided that includes: controlling a gate voltage of a first NMOS transistor coupled between a power supply node for a memory power supply voltage and an input node to a bitcell array to regulate a voltage of the input node to equal a retention voltage while maintaining a first PMOS transistor coupled between the power supply node and the input node off during a light-sleep mode for the bitcell array; and switching the first PMOS transistor on to charge the input node to the memory power supply voltage during an active mode for the bitcell array.

These and other advantageous features may be better appreciated through the following detailed description.

### BRIEF DESCRIPTION OF THE DRAWINGS

FIG. 1 illustrates a memory including an analog voltage gate driver in accordance with an aspect of the disclosure.

FIG. 2 illustrates a memory including a pair of banks powered by head switch circuits in accordance with an aspect of the disclosure.

FIG. 3 is a flowchart for a method of operation of a memory including an analog gate voltage driver in accordance with an aspect of the disclosure.

FIG. 4 illustrates some example electronic systems including a memory having an analog voltage gate driver in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

In the following discussion, SRAM is used as an example to illustrate the concept. Nonetheless, one of skill in the art would ready recognize that the power management techniques discussed herein are generally applicable to other types of embedded memories in a chip. The bitcells for an SRAM are arranged into rows and columns. Each row is traversed by a corresponding word line whereas a pair of bit lines traverses each column. It may thus be appreciated that the word line length and the bit line length increases as the row and column size is increased. But this increased length comes at the cost of increased capacitance, which slows the memory operating speed. The bitcells are thus typically arranged into banks instead of into one large array. Each bank of bitcells has its own rows and columns. In this fashion, the capacitance for the word lines and the bit lines may be kept to a manageable level for increased memory speed.

Although the arrangement of the bitcells into banks is thus advantageous, it may be cumbersome for each bank to have an independently regulated memory domain (MX) power supply voltage. Instead, the banks typically share a memory power supply voltage. A power source such as a switching power supply converter regulates the memory power supply voltage that is supplied to a power supply rail or node. Each bank couples to the power supply node through corresponding head switch transistors. Depending upon the current operating requirements, some banks may be active whereas other banks may be idle. The active banks operate in the active mode and thus the memory power supply voltage is at its elevated level. But with the memory power supply voltage at its elevated level, the idle banks cannot be transitioned to the retention mode. The idle banks then have elevated leakage due to their operation in the active mode rather than in the retention mode.

To avoid the leakage of traditional power modes, a memory with a plurality of banks is provided in which a bitcell array and in some implementations an MX periphery in each bank is powered through an at least one head switch circuit formed by a parallel combination of at least one PMOS head switch transistor and at least one NMOS head switch transistor. For discussion clarity, the following discussion will assume that the at least one PMOS head switch transistor and the at least one NMOS head switch transistor are both just one transistor each, but it will be appreciated that more than one transistor may be used in alternative implementations. Similarly, the head switch circuit for a bank will be referred to as a single head switch circuit but it will be appreciated that a plurality of head switch circuits may be used to power the bitcells and the MX periphery of a bank. The powering of the MX periphery by the head switch circuit is optional such that there are implementations in which only the bitcell array is powered by the head switch circuit and there are alternative implementations in which the bitcell array and the MX periphery is powered by the head switch circuit. The bitcell array for a bank (and the MX periphery depending upon the implementation) will thus also be denoted herein as the load for a head switch circuit.

The head switch circuit couples between a power supply node for the memory power supply voltage and an input power node to the load. A memory controller controls a gate voltage of the first PMOS transistor such that it is fully on during an active mode (which may also be denoted as a default mode) for the memory. The bitcell array is thus powered by the memory power supply voltage during the active mode. But during a light-sleep mode for the bank, the memory controller switches off the first PMOS transistor. An analog gate voltage driver controls an analog gate voltage of the first NMOS transistor such that the first NMOS transistor is neither fully on nor off but instead is partially on. Due to this partially-on state, the first NMOS transistor passes a retention voltage that is smaller than the memory power supply voltage. This retention voltage allows the bitcell array to retain its stored binary content but reduces the leakage current as compared to the active mode. Although the bank is thus in the light-sleep mode, the memory power supply voltage remains at its elevated level as compared to the retention level for powering other banks that may be in the active mode. The result is quite advantageous in that the banks operating in the active mode do not force the banks operating in the light-sleep mode to be powered by the elevated memory power supply voltage. In this fashion, the light-sleep mode banks will conduct a reduced amount of leakage current despite the memory power supply voltage remaining at the elevated level for the banks operating in the active mode.

The analog control of the first NMOS transistor may be contrasted with the traditional digital control used for the first PMOS transistor. With respect to this digital control, the gate voltage of the first PMOS transistor is either a binary one (charged to the memory power supply voltage) or a binary zero (discharged to ground). Such a gate voltage is denoted herein as a digital gate voltage. The first PMOS transistor switch transistor is fully on in response to its gate being grounded and switched off with its gate being charged to the memory power supply voltage. But in the analog control of the first NMOS transistor disclosed herein, the gate voltage is neither a binary zero nor a binary one but instead is some fraction of the memory power supply voltage such that the first NMOS transistor is neither fully on nor fully off but instead is partially on.

In the light-sleep mode, the periphery CX power domain may be collapsed such that the head switch transistors for the periphery CX domain are switched off. But the MX periphery and the bitcell array for a bank are maintained partially on through the analog gate control from the analog gate voltage driver so that these domains remained powered by a reduced power supply voltage (which is also denoted as a core power supply voltage herein). The bitcells thus retain their stored binary content since the core power supply voltage is at the retention level. Although keeping the periphery MX domain powered during the light-sleep mode allows the periphery MX domain to conduct some amount of leakage current, the transition speed from the light-sleep mode to the active mode is increased as compared to collapsing the periphery MX domain. However, in alternative implementations, only the bitcell domain would remain powered in the light-sleep mode. This resulting shutdown of the periphery MX domain in the light-sleep mode reduces the power loss from leakage currents at the cost of an increased transition time from the light-sleep mode to the active mode. Thus, the following discussion will be directed to implementations in which the periphery MX domain remains powered during the light-sleep mode without loss of generality.

During the light-sleep mode, both the bitcell array and the associated periphery MX domain for a bank act as a load to their respective head switch transistors that conducts a certain amount of leakage current. The analog gate driver includes a replica load circuit that models this load. In one implementation, the replica load circuit may be formed by duplicating the bitcell array and the circuitry within the periphery MX domain. Alternatively, the replica load circuit may be formed so as to conduct a leakage current having a known proportionality to the leakage current conducted by the bitcell array and the periphery MX domain.

In addition to the replica load circuit, the analog gate voltage driver includes a replica NMOS transistor. Analogously as discussed for the replica load circuit, the replica NMOS transistor may be sized to be an exact replica of each first NMOS transistor for the bitcell domain and the periphery MX domain. Alternatively, the replica NMOS transistor may be sized to have a known proportionality to the first NMOS transistor size. The NMOS replica transistor has a drain coupled to the power supply rail for the memory power supply voltage and a source coupled to an input node to the replica load circuit. The analog gate voltage driver generates an analog gate voltage for the replica NMOS transistor so that the source voltage of the replica NMOS transistor is maintained at the retention level. The same analog gate voltage couples to the gates of the first NMOS transistor(s) for the bitcell array and the associated periphery MX domain. The bitcell array and the associated periphery MX domain is thus powered at the retention level during the light-sleep mode. In this fashion, an array of banks may share a memory power supply voltage such that some of the banks may be powered by the elevated voltage level of the memory power supply voltage in the active mode while other ones of the banks may be powered by the retention voltage level in the light-sleep mode.

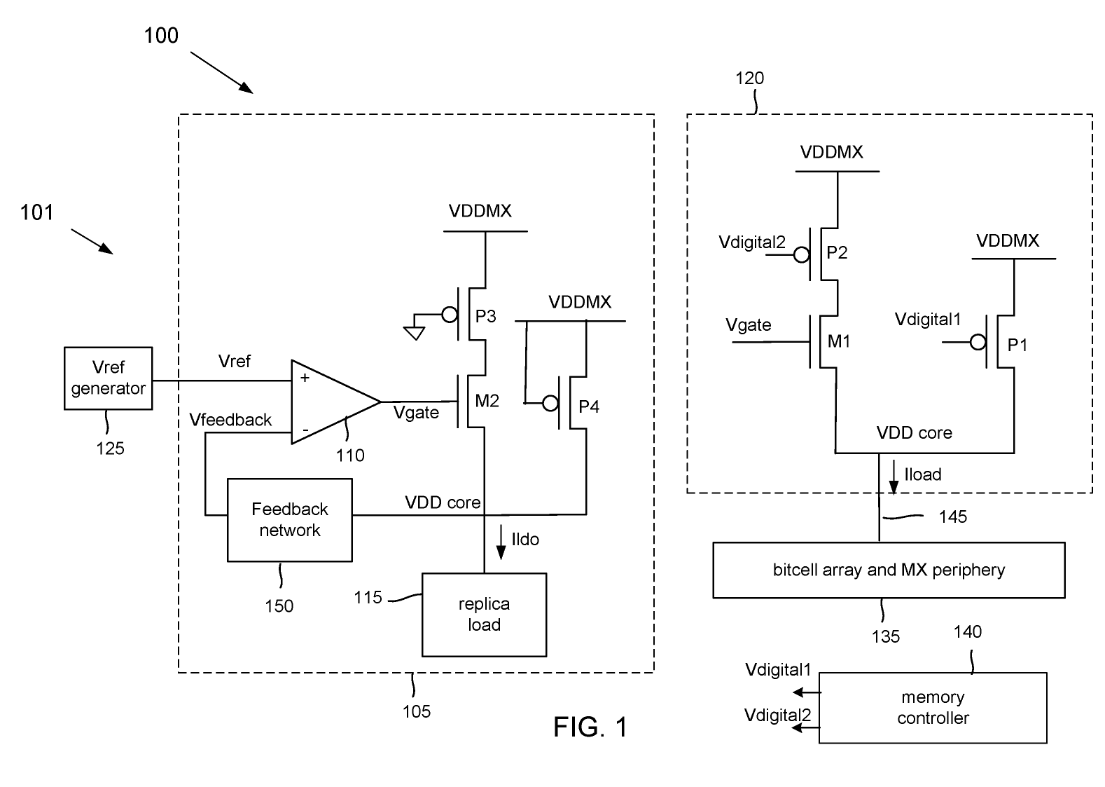

An example bank 100 with a head switch circuit 120 is shown in FIG. 1. A first NMOS transistor M1 that is also denoted herein as a first head switch transistor couples in parallel with a first PMOS transistor P1 that is also denoted herein as a second head switch transistor. A drain of the transistor P1 and a source of the transistor M1 couple together to a power input node 145 to a bitcell array and an MX periphery 135 for the bank 100. The power input node 145 is also an output node of the head switch circuit 120. A source of the transistor P1 couples to a power supply node for the memory power supply voltage (VDDMX). A memory controller 140 controls a digital gate voltage (Vdigital1) of the transistor P1 so that the transistor P1 is fully on during an active mode for the bank 100 in which the bitcell array and MX periphery 135 is powered by the memory power supply voltage. The memory controller 140 controls the digital gate voltage Vdigital1 so that the transistor P1 is off during a light-sleep mode in which the bitcell array and MX periphery 135 is powered with a retention power supply voltage. The memory controller 140 also controls the digital gate voltage Vdigital1 so that the transistor P1 is off during a deep-sleep mode for the bank 100 in which the bitcell array and MX periphery is powered down.

In some implementations, a drain of the transistor M1 may couple directly to the power supply node. But since the transistor M1 introduces a threshold voltage drop when it is powering the power input node 145, transistor M1 may be smaller than the transistor P1 so as to have a reduced threshold voltage. The reduced threshold voltage may lead to excessive leakage during the deep-sleep mode. Thus, the drain of the transistor M1 may couple to the power supply node through a PMOS transistor P2. The memory controller 140 controls a digital gate voltage (Vdigital2) of the transistor P2 so that is fully on during the active mode and the light-sleep mode but off during the deep-sleep mode to reduce leakage currents that would otherwise be conducted by the transistor M1.

A voltage regulator such as a low-dropout regulator (LDO) 105 controls an analog gate voltage (Vgate) of the transistor M1 to regulate a core power supply voltage at the drain of the transistor M1. The LDO 105 includes a differential amplifier 110 that develops the analog gate voltage Vgate by driving a gate of a replica NMOS head switch transistor M1 having a drain coupled to the power supply node through a PMOS transistor P3 that is a replica of the transistor P2. A gate of the transistor P3 may be grounded so that it stays on during operation of the LDO 105. A source of the transistor M2 couples to a power input node for a replica load 115. The replica load 115 draws an LDO current (Ildo) that is either a replica of or proportional to a load current (Iload) conducted by the bitcell array and MX periphery 135 during the light-sleep mode. Through Ohm’s law, the conducting of the LDO current through the replica load 115 to ground develops a core power supply voltage (VDD core) at the source of the transistor M2 due to the resistance of the replica load 115. The core power supply voltage is also denoted herein as a bitcell power supply voltage. To regulate the core power supply voltage to equal the retention level for the bitcell array and MX periphery 135, the core power supply voltage couples through a feedback network 150 to an input terminal (e.g., an inverting input terminal) of a differential amplifier 110.

The feedback network 150 may comprise a voltage divider such that it couples a divided version of the core power supply voltage as a feedback voltage (Vfeedback) to the inverting input terminal of the differential amplifier 110. Alternatively, the feedback network 150 may be a lead or connector such that the feedback voltage equals the core power supply voltage. To regulate the core power supply voltage to equal the retention level, the differential amplifier 110 controls the analog gate voltage (Vgate) of the transistor M2 so that the feedback voltage equals a reference voltage (Vref) received at an input terminal (e.g., a non-inverting input terminal) of the differential amplifier 110. A suitable reference voltage generator 125 such as a bandgap reference generator generates the reference voltage. To further replicate the loading within the head switch circuit 140, the LDO 105 may include a PMOS transistor P4 that replicates the transistor P1. The transistor P4 thus couples between the power supply node and the input node to the replica load 115. To maintain the transistor P4 off, its gate may be coupled to the power supply node.

The active level of the memory power supply voltage VDDMX and the retention level of the core power supply voltage will vary such as depending upon the process node used to construct the memory 100. In one implementation, the active level may be 0.8V whereas the retention level may be 0.5V but it will be appreciated that these voltages may be higher or lower in alternative implementations. Regardless of the exact values, the retention value will typically be significantly lower than the active value to reduce the leakage current during the light-sleep mode.

As used herein, a digital signal such as a digital gate voltage is deemed to be asserted when the binary signal has a logical true value, regardless of whether the logical true value is expressed using an active-low or active-high convention. In an active-low convention, a binary signal is asserted by being grounded and de-asserted by being asserted to the memory power supply voltage. In an active-high convention, a binary signal is asserted by being charged to the memory power supply voltage and de-asserted by being grounded. In contrast to the digital gate voltages Vdigital1 and Vdigital2, the analog gate voltage Vgate from the analog voltage gate driver 101 only partially switches on the transistors M1 and M2 – the transistors M1 and M2 are neither fully on nor fully off during the light-sleep mode and during the active mode. In one implementation, the analog gate voltage driver 101 may be deemed to form a means for generating an analog gate voltage for an NMOS head switch transistor to maintain the NMOS head switch transistor partially on during a light-sleep mode for a bitcell array.

Note the advantages of the head switch circuit 120. The LDO 105 driving the gate of the transistor M1 may be considered to be in a source follower amplifier configuration. In contrast, if the transistor M1 were instead a PMOS transistor having an analog gate voltage driven by the LDO 105, the resulting combination may be deemed to be in a common source amplifier configuration. As compared to a source follower amplifier, a common source amplifier will typically have higher gain. In contrast, the “gain” of the LDO 105 driving the gate of the transistor M1 is less than one. This reduced gain reduces the effect of any mismatch between the transistors M1 and M2. Moreover, the source follower configuration simplifies the implementation of the differential amplifier 110. In addition, the parallel combination of the transistor M1 and the transistor P1 in the head switch circuit 120 eliminates any need to multiplex with regard to driving the gate of the transistor M1 so as to transition between the light-sleep and active modes. There is thus no multiplexer leakage in the head switch circuit 120.

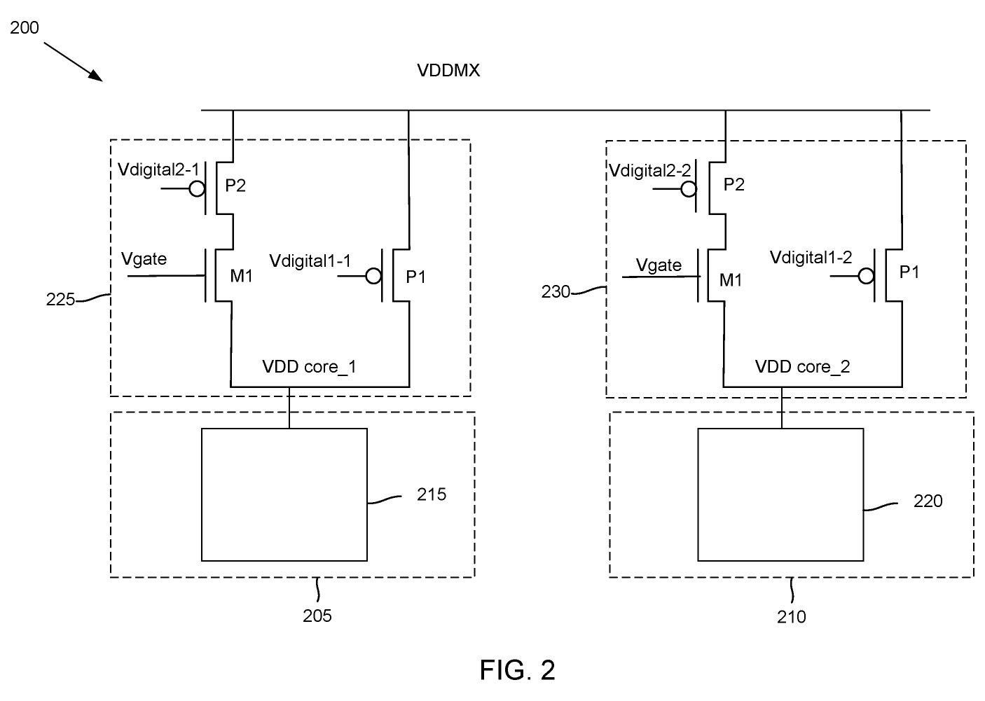

The resulting head switch circuit is also advantageous as the power supply node for the memory power supply voltage may then be shared by multiple banks with some of the banks being in the active mode whereas idle ones of the banks may be in the light-sleep mode despite the memory power supply voltage being maintained at the active level. For example, a memory 200 with a plurality of banks including a first bank 205 and a second bank 210 is shown in FIG. 2. For illustration clarity, the first bank 205 is shown as including a bitcell array and MX periphery 215 that is powered by a single head switch circuit 225 but it will be appreciated that a plurality of head switch circuits may be used in alternative implementations. Similarly, the second bank 210 is shown including a bitcell array and MX periphery 220 that is powered by a single head switch circuit 230 but additional head switch circuits may be used in alternative implementations.

The head switch circuits 225 and 230 are analogous to the head switch circuit 120 and thus each includes the parallel combination of the transistors M1 and P1 and the additional transistor P2. To allow the independent control of whether the banks 205 and 210 are in the active mode or the light-sleep mode, the digital gate voltages Vdigital1 and Vdigital2 of the head switch circuit 120 are differentiated into a set Vdigital1-1 and Vdigital2-1 for the head switch circuit 225 and a set Vdigital1-2 and Vdigital2-2 for the head switch circuit 230. Suppose that the first bank 205 is in the active mode whereas the second bank 210 is idle and is thus transitioned to the light-sleep mode. A memory controller (not illustrated) may thus ground switch on the transistor P1 in the head switch circuit 225 by grounding the digital gate voltage Vdigital1-1. At the same time, the memory controller may switch off the transistor P1 in the head switch circuit 225 by asserting the digital gate voltage Vdigital1-2 to the memory power supply voltage. Both transistors M1 remain partially on with the transistors P2 being fully on. A supply voltage VDD core_1 passed by the head switch circuit 225 will thus equal the memory power supply voltage whereas a supply voltage VDD core_2 passed by the head switch circuit 230 will be at the retention level. In this fashion, a plurality of banks may share a common power supply node without forcing each bank to remain in the active mode should one (or more) of the banks operate in the active mode. Should none of the banks be in the active mode, the memory power supply voltage may be dropped to the retention level.

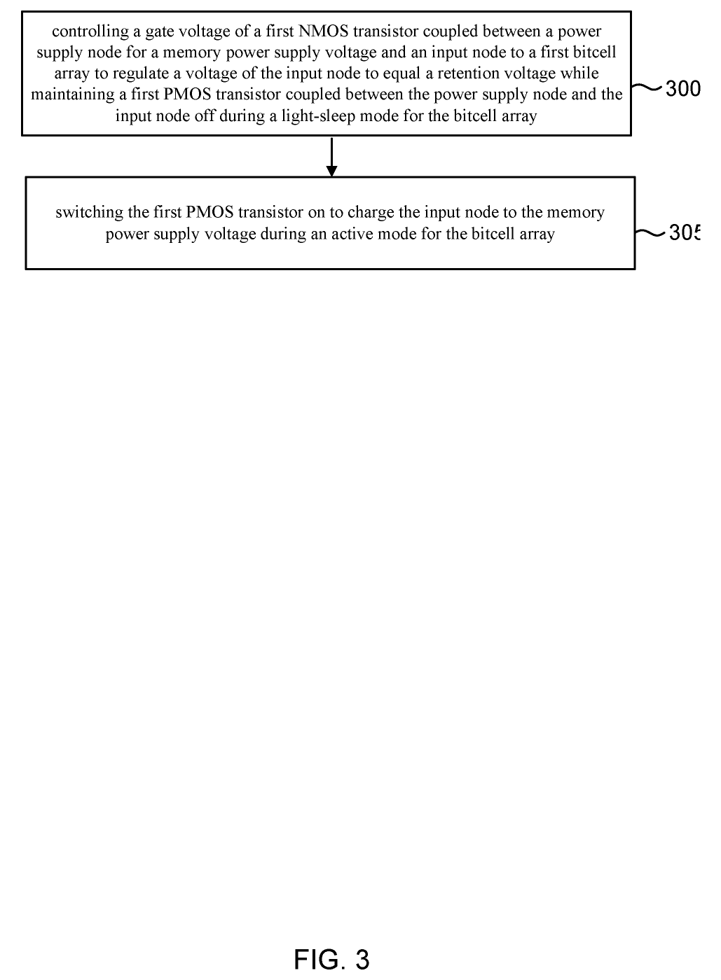

An example method of operation for a memory will now be discussed with respect to the flowchart of FIG. 3. The method includes an act 300 of controlling a gate voltage of a first NMOS transistor coupled between a power supply node for a memory power supply voltage and an input node to a first bitcell array to regulate a voltage of the input node to equal a retention voltage while maintaining a first PMOS transistor coupled between the power supply node and the input node off during a light-sleep mode for the bitcell array. The control of the analog gate voltage Vgate by the analog gate voltage driver 101 of FIG. 1 while the memory controller 135 maintains the transistor P1 off is an example of act 300. The method also includes an act 305 of switching the first PMOS transistor on to charge the input node to the memory power supply voltage during an active mode for the bitcell array. The switching on of the transistor P1 is an example of act 305.

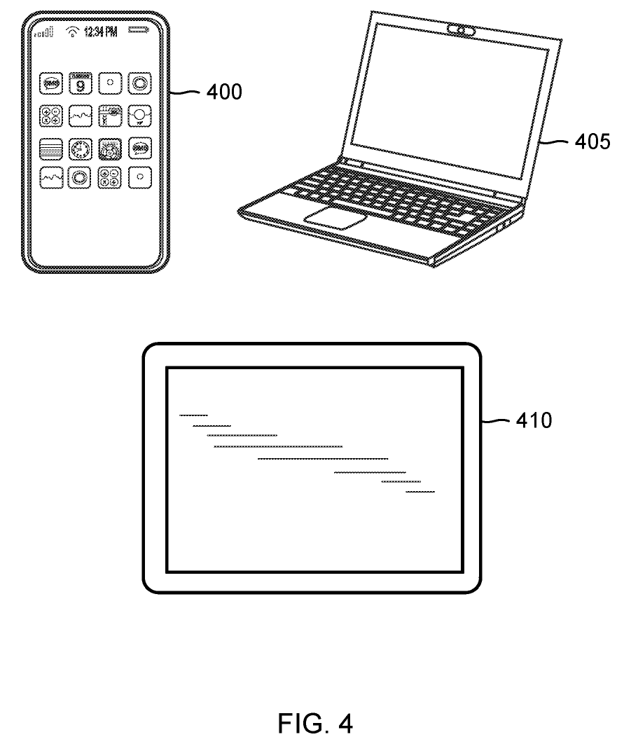

A memory as disclosed herein may be incorporated in a wide variety of electronic systems. For example, as shown in FIG. 4, a cellular telephone 400, a laptop computer 405, and a tablet 410 may all include a memory in accordance with the disclosure. Other exemplary electronic systems such as a video player, a communication device, and a personal computer may also be configured with a memory constructed in accordance with the disclosure.

Some example implementations are described by the following numbered clauses:

Clause 1. A memory, comprising:
a power supply node for a memory power supply voltage;
a first n-type metal-oxide semiconductor (NMOS) transistor;
a first p-type metal-oxide semiconductor (PMOS) transistor;
a bitcell array having an input power node for a bitcell power supply voltage, wherein the first NMOS transistor and the first PMOS transistor are coupled in parallel between the power supply node and the input power node; and
a voltage regulator configured to control an analog gate voltage of the first NMOS transistor to regulate the bitcell power supply voltage.

Clause 2. The memory of clause 1, further comprising:
a controller configured to drive a digital gate voltage of the first PMOS transistor.

Clause 3. The memory of any of clauses 1-2, wherein the voltage regulator includes a replica load circuit configured to replicate a leakage current of the bitcell array.

Clause 4. The memory of clause 3, wherein the voltage regulator further includes a second NMOS transistor having a size that is proportional to a size of the first NMOS transistor.

Clause 5. The memory of clause 4, wherein the size of the second NMOS transistor equals the size of the first NMOS transistor.

Clause 6. The memory of any of clauses 4-5, wherein a gate of the second NMOS transistor is coupled to a gate of the first NMOS transistor, and wherein the voltage regulator comprises a linear dropout regulator including a differential amplifier configured to compare a feedback voltage from a source of the second NMOS transistor to a reference voltage to control the analog gate voltage.

Clause 7. The memory of clause 6, further comprising:
a second PMOS transistor coupled between the first NMOS transistor and the power supply node, wherein the controller is further configured to drive a digital gate voltage of the second PMOS transistor.

Clause 8. The memory of clause 6, further comprising:
a feedback network configured to couple the feedback voltage to an input terminal of the differential amplifier.

Clause 9. The memory of clause 8, wherein the feedback network comprises a voltage divider.

Clause 10. The memory of clause 6, further comprising:
a bandgap reference generator configured to generate the reference voltage.

Clause 11. The memory of clause 6, further comprising:
a memory periphery coupled to the input power node, wherein the replica load circuit is further configured to replicate a leakage current of the memory periphery.

Clause 12. A memory, comprising:
a voltage rail for a memory power supply voltage;
a plurality of banks, each bank including an array of bitcells;
a plurality of head switch circuits corresponding to the plurality of banks on a one-to-one basis, wherein each bank’s array of bitcells is coupled to the voltage rail through a corresponding head switch circuit from the plurality of head switch circuits, and wherein each head switch circuit includes:
   a first NMOS transistor coupled between the voltage rail and an output node of the head switch circuit; and
   a voltage regulator configured to control an analog gate voltage of the first NMOS transistor during both a light-sleep mode and an active mode for the corresponding bank.

Clause 13. The memory of clause 12, wherein the voltage regulator includes a replica load circuit configured to replicate a leakage current of each array of bitcells.

Clause 14. The memory of clause 13, wherein the voltage regulator further includes a second NMOS transistor having a size that equals a size of each first NMOS transistor.

Clause 15. The memory of clause 14, wherein a gate of the second NMOS transistor is coupled to a gate of each first NMOS transistor, and wherein the voltage regulator further includes a differential amplifier configured to compare a feedback voltage from a source of the second NMOS transistor to a reference voltage to control the analog gate voltage.

Clause 16. The memory of clause 14, wherein each head switch circuit includes a first PMOS transistor coupled between the voltage rail and the output node of the head switch circuit, the memory further comprising:
a memory controller configured to control a digital gate voltage of each first PMOS transistor.

Clause 17. The memory of clause 16, wherein each first PMOS transistor is larger than each first NMOS transistor.

Clause 18. The memory of any of clauses 12-17, wherein the memory is included within a cellular telephone.

Clause 19. A method of powering a memory, comprising:
controlling a gate voltage of a first NMOS transistor coupled between a power supply node for a memory power supply voltage and an input node to a bitcell array to regulate a voltage of the input node to equal a retention voltage while maintaining a first PMOS transistor coupled between the power supply node and the input node off during a light-sleep mode for the bitcell array; and
switching the first PMOS transistor on to charge the input node to the memory power supply voltage during an active mode for the bitcell array.

Clause 20. The method of clause 19, wherein controlling the gate voltage of the first NMOS transistor comprises:
replicating a load current of the bitcell array in a replica load circuit during the light-sleep mode; and
driving a gate of a second NMOS transistor coupled between the power supply node and an input terminal to the replica load circuit with the gate voltage of the first NMOS transistor while comparing a voltage of the input terminal to a reference voltage.

As those of some skill in this art will by now appreciate and depending on the particular application at hand, many modifications, substitutions and variations can be made in and to the materials, apparatus, configurations and methods of use of the devices of the present disclosure without departing from the scope thereof as defined by the appended claims. In light of this, the scope of the present disclosure should not be limited to that of the particular implementations illustrated and described herein, as they are merely by way of some examples thereof, but rather, should be fully commensurate with that of the claims appended hereafter and their functional equivalents.

What is claimed is:

1. A memory, comprising:
a power supply node for a memory power supply voltage;
a first n-type metal-oxide semiconductor (NMOS) transistor;
a first p-type metal-oxide semiconductor (PMOS) transistor;
a bitcell array having an input power node for a bitcell power supply voltage, wherein the first NMOS transistor and the first PMOS transistor are coupled in parallel between the power supply node and the input power node; and
a voltage regulator configured to control an analog gate voltage of the first NMOS transistor to regulate the bitcell power supply voltage.

2. The memory of claim 1, further comprising:
a controller configured to drive a digital gate voltage of the first PMOS transistor.

3. The memory of claim 1, wherein the voltage regulator includes a replica load circuit configured to replicate a leakage current of the bitcell array.

4. The memory of claim 3, wherein the voltage regulator further includes a second NMOS transistor having a size that is proportional to a size of the first NMOS transistor.

5. The memory of claim 4, wherein the size of the second NMOS transistor equals the size of the first NMOS transistor.

6. The memory of claim 4, wherein a gate of the second NMOS transistor is coupled to a gate of the first NMOS transistor, and wherein the voltage regulator comprises a low-dropout regulator including a differential amplifier configured to compare a feedback voltage from a source of the second NMOS transistor to a reference voltage to regulate the analog gate voltage.

7. The memory of claim 2, further comprising:
a second PMOS transistor coupled between the first NMOS transistor and the power supply node, wherein the controller is further configured to drive a digital gate voltage of the second PMOS transistor.

8. The memory of claim 6, further comprising:
a feedback network configured to couple the feedback voltage to an input terminal of the differential amplifier.

9. The memory of claim 8, wherein the feedback network comprises a voltage divider.

10. The memory of claim 6, further comprising:
a bandgap reference generator configured to generate the reference voltage.

11. The memory of claim 6, further comprising:
a memory periphery coupled to the input power node, wherein the replica load circuit is further configured to replicate a leakage current of the memory periphery.

12. A memory, comprising:
a voltage rail for a memory power supply voltage;
a plurality of banks, each bank including an array of bitcells;
a plurality of head switch circuits corresponding to the plurality of banks on a one-to-one basis, wherein each bank’s array of bitcells is coupled to the voltage rail through a corresponding head switch circuit from the plurality of head switch circuits, and wherein each head switch circuit includes:
a first NMOS transistor coupled between the voltage rail and an output node of the head switch circuit; and
a voltage regulator configured to control an analog gate voltage of the first NMOS transistor during both a light-sleep mode and an active mode for the corresponding bank.

13. The memory of claim 12, wherein the voltage regulator includes a replica load circuit configured to replicate a leakage current of each array of bitcells.

14. The memory of claim 13, wherein the voltage regulator further includes a second NMOS transistor having a size that equals a size of each first NMOS transistor.

15. The memory of claim 14, wherein a gate of the second NMOS transistor is coupled to a gate of each first NMOS transistor, and wherein the voltage regulator further includes a differential amplifier configured to compare a feedback voltage from a source of the second NMOS transistor to a reference voltage to control the analog gate voltage.

16. The memory of claim 14, wherein each head switch circuit includes a first PMOS transistor coupled between the voltage rail and the output node of the head switch circuit, the memory further comprising:
a memory controller configured to control a digital gate voltage of each first PMOS transistor.

17. The memory of claim 16, wherein each first PMOS transistor is larger than each first NMOS transistor.

18. The memory of claim 12, wherein the memory is included within a cellular telephone.

19. A method of powering a memory, comprising:
controlling a gate voltage of a first NMOS transistor coupled between a power supply node for a memory power supply voltage and an input node to a bitcell array to regulate a voltage of the input node to equal a retention voltage while maintaining a first PMOS transistor coupled between the power supply node and the input node off during a light-sleep mode for the bitcell array; and
switching the first PMOS transistor on to charge the input node to the memory power supply voltage during an active mode for the bitcell array.

20. The method of claim 19, wherein controlling the gate voltage of the first NMOS transistor comprises:
replicating a load current of the bitcell array in a replica load circuit during the light-sleep mode; and
driving a gate of a second NMOS transistor coupled between the power supply node and an input terminal to the replica load circuit with the gate voltage of the first NMOS transistor while comparing a voltage of the input terminal to a reference voltage.
